(19) United States
(12) Patent Application Publication
(10) Pub. No.: US 2018/0089984 A1
(43) Pub. Date: Mar. 29, 2018

(54) DEVICE, SYSTEM AND METHOD FOR DETECTING DEGRADATION OF A FLEXIBLE CIRCUIT

(71) Applicant: Intel Corporation, Santa Clara, CA (US)

(72) Inventors: Vijay Krishnan Subramanian, Gilbert, AZ (US); Steven A. Klein, Chandler, AZ (US); Pramod Malatkar, Chandler, AZ (US); Rajendra C. Dias, Phoenix, AZ (US); Aleksandar Aleksov, Chandler, AZ (US); Jason P. Glumbik, Hillsboro, OR (US); Nadine L. Dabby, Palo Alto, CA (US)

(21) Appl. No.: 15/277,811

(22) Filed: Sep. 27, 2016

(51) Int. Cl. G08B 21/18; H05K 1/02; H05K 1/18; G01R 31/28

(52) U.S. Cl. CPC G08B 21/182; H05K 1/028; H05K 2201/10151; G01R 31/2839; G01R 31/2846; H05K 1/181

(57) ABSTRACT

Techniques and mechanisms for determining a level of degradation of flexible circuitry. In an embodiment, a flexible substrate has disposed therein first circuitry and one or more components coupled thereto, the one or more components to monitor a physical property of the first circuitry. Further disposed in or on the flexible substrate are memory resources to store predefined reference information which corresponds amounts of the physical property each with a different respective level of degradation. Evaluation logic accesses the reference information to determine, based on a detected amount of the physical property, a level of degradation of second circuitry. In another embodiment, the second circuitry is more flexible, as compared to the first circuitry.

### BACKGROUND

### 1. Technical Field

Embodiments described herein generally relate to the field of electronic devices and, more particularly, to detecting properties of flexible circuitry.

### 2. Background Art

Flexible circuitry, in which electronic circuits are deposited on flexible substrates or embedded in flexible materials, have the potential to be utilized in many types of devices, including wearable devices and other implementations. The flexing of flexible circuitry will inevitably stress electronic components to some degree, and may cause device failure over time. As the variety and proliferation of flexible circuitry technologies continues to grow, there is expected to be an increased significance placed on the reliability of flexible circuit structures in different applications.

### BRIEF DESCRIPTION OF THE DRAWINGS

The various embodiments of the present invention are illustrated by way of example, and not by way of limitation, in the figures of the accompanying drawings and in which:

FIG. 1 is a functional block diagram illustrating elements of a device including flexible circuitry according to an embodiment.

FIG. 2 is a flow diagram illustrating elements of a method for operating a flexible circuit according to an embodiment.

FIG. 3 is a perspective view of a flexible circuit device according to an embodiment.

FIGS. 4A, 4B are layout diagrams illustrating elements of respective flexible circuit devices each according to a corresponding embodiment.

FIGS. 5A-5C are layout diagrams illustrating elements of respective flexible circuit devices each according to a corresponding embodiment.

FIGS. 6A, 6B are cross-sectional diagrams illustrating respective elements of flexible circuitry each according to a corresponding embodiment.

FIG. 6C is a layout diagram illustrating elements of flexible circuitry according to an embodiment.

FIG. 7 is a functional block diagram illustrating elements of a computer system according to an embodiment.

FIG. 8 is a functional block diagram illustrating elements of a computer device according to an embodiment.

### DETAILED DESCRIPTION

Embodiments discussed herein variously provide techniques and mechanisms for a device to determine a level of degradation of one or more of its own flexible circuit structures. In some embodiments, a flexible circuit device includes one or more conductive traces, where a physical property of the one or more conductive traces (e.g., including an impedance) is susceptible to change over time due to stresses imposed by flexing of the device. As used herein, “flexing” may include bending, twisting, stretching and/or other such mechanical deformation. The flexible circuit device may include one or more components which operate to detect a current amount of such a physical property. In such an embodiment, the one or more components may access predefined reference information to determine, based on the detected amount of the physical property, a corresponding amount of degradation by one or more other flexible circuit structures of the device.

A flexible circuit (such as that of a wearable electronics device) may monitor for—and in some embodiments, predict—a failure of its own flexible circuitry. For example, a wearable health monitor (WHM) may perform a failure analysis to locally determine if the WHM was used outside of a specified range of flexing (e.g., stretching, torsion and/or bending). A monitor component of such a flexible circuit may identify an amount of circuit degradation with a value other than a mere one-bit binary (e.g., “0” for pass, “1” for fail“) output. In an embodiment, circuit degradation may be identified with an intermediate value representing a degradation level between some baseline level and another level which, for example, corresponds to an expected failure of some or all flexible circuitry. An amount of flexible circuit degradation may be determined locally at a device during manufacture processing or, for example, during real-world operation of the device by a user.

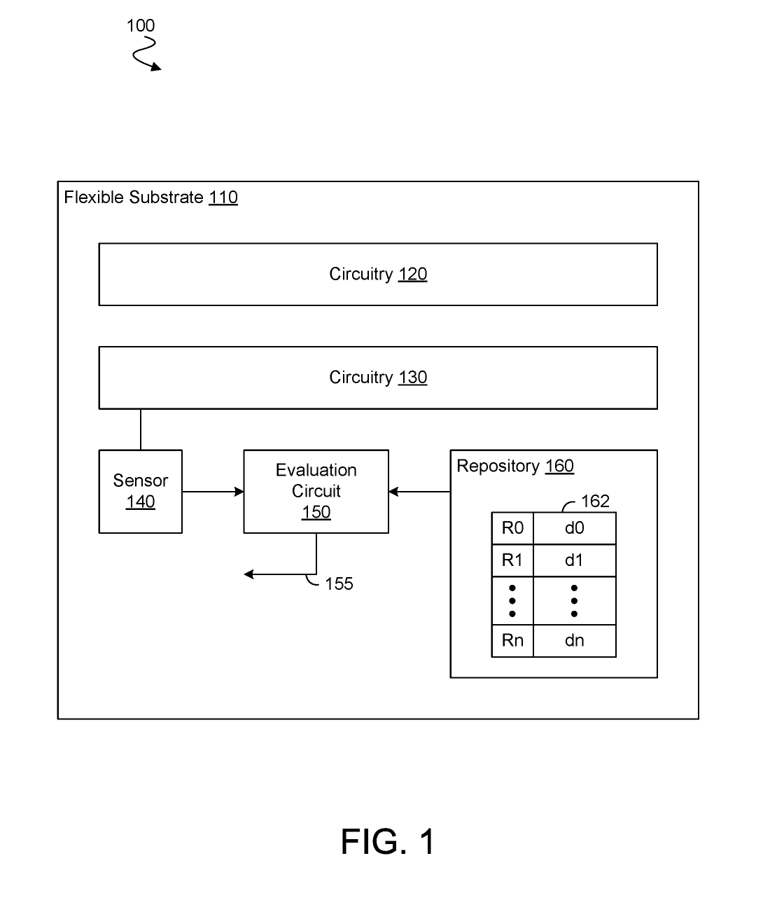

FIG. 1 illustrates elements of a device 100 to detect degradation of circuit structures according to an embodiment. Device 100 is one example of an embodiment including circuitry which is capable of being bent, stretched, twisted and/or otherwise flexed. In the illustrative embodiment shown, device 100 includes a flexible substrate 100 and circuitry 120 disposed therein or thereon, wherein some or all of circuitry 120 is susceptible to degradation due to stress resulting from flexing of device 100.

Flexible substrate 110 may include any of a variety of dielectric materials adapted, for example, from conventional flexible circuit techniques. In one illustrative embodiment, flexible substrate 110 comprises an epoxide, acrylic, polyamide, polydimethylsiloxane (PDMS), thermoplastic polyurethane, any of a variety of rubbers (e.g., a nitrile rubber, butyl rubber, etc.) and/or the like. In one embodiment, flexible substrate 110 includes a laminate comprising multiple flexible dielectric layers. Circuitry 120—e.g., encapsulated by a dielectric material of flexible substrate 110—may include any of a variety of active circuit elements and/or passive circuit elements, and conductive traces to variously interconnect such circuit elements. For example, circuitry 120 may include one or more of a register, display element (e.g., a light emitting diode), a wireless communication circuit (e.g., including radio frequency identification circuitry), a memory, processor, controller, application-specific integrated circuit and/or the like. However, circuitry 120 may include any of the variety of additional and/or alternative circuit components, and some embodiments are not limited to a particular functionality that might be provided by circuitry 120.

Use of device 100 may include a flexing of circuit structures in flexible substrate 110, where such flexing contributes to a degradation of at least some of circuitry 120 over time. Some embodiments variously provide techniques and/or mechanisms to monitor one or more physical properties of circuitry disposed in or on flexible substrate 110, where an amount of degradation at circuitry 120 may be determined based on such monitoring. For example, flexible substrate 110 may have disposed therein or thereon circuitry 130 and a sensor 140 coupled thereto. Circuitry 130 may include one or more trace portions (e.g., including one or more conductive loops) which are prone to being bent, stretched and/or otherwise flexed during operation of device 100. Although shown as being distinct from circuitry 130, circuitry 120 may include some or all of circuitry 130, in another embodiment.

In combination with the one or more trace portions of circuitry 130, sensor 140 may function as a gauge to detect the effect of stress from flexing of device 100. Sensor 140 may be coupled to receive an output signal from circuitry 130, where such an output signal indicates a physical property (e.g., including a resistance) of at least some portion of circuitry 130. For example, sensor 140 may include circuitry configured to provide a test signal to circuitry 130, and detect a response by circuitry 130 to that test signal. Device 100 may further comprise an evaluation circuit 150 disposed in or on flexible substrate 110, where evaluation circuit 150 is coupled to receive an output from sensor 140 and to determine, based on such output, a characteristic of the corresponding circuit response by circuitry 130. Such determining may include evaluation circuit 150 identifying a voltage level, a current level, a frequency and/or other such characteristic of the circuit response, where the characteristic directly or indirectly indicates a current amount of a physical property (e.g., an impedance) of circuitry 130. By way of illustration and not a limitation, sensor 140 and evaluation circuit 150 may operate together as a resistometer (e.g., where sensor 140 includes a Wheatstone bridge circuit) configured to determine a current amount of resistance of one or more conductive traces in circuitry 130. Any of the variety of conventional detector circuit architectures may be adapted, in different embodiments, for inclusion in sensor 140 to facilitate detection of a resistance, capacitance, inductance and/or other physical property of circuitry 130.

The detected amount of resistance (or other physical property) of circuitry 130 may provide a basis for determining a corresponding level of degradation of some or all circuit structures—e.g., including circuitry 120—that are disposed in or on flexible substrate 110. For example, flexible substrate 110 may further comprise a repository 160 which stores reference information corresponding various amounts of a physical property (e.g., including a resistance) of circuitry 130 each with a different respective level of degradation of circuitry 120. In the illustrative embodiment shown, repository 160 includes memory cells (e.g., comprising a flexible flash memory or other such non-volatile memory) operable to store a table 162 comprising entries which associate resistance values r0, r1, . . . , rn (or other values based on such resistance values) with respective degradation values d0, d1, . . . , dn. The correspondence of levels of a physical property to respective amounts of circuit degradation may be represented by any of the variety of additional or alternative data structures, in various embodiments.

Reference information stored by repository 160 may include respective data for each of the plurality of levels of degradation, where one or more of such levels of degradation—e.g., including at least two such levels—allow for continued operation of device 100. For example, one or more of d0, d1, . . . , dn may each be a level of degradation less than some predetermined maximum threshold level which represents an expected point of failure of circuitry 120. In one embodiment, the levels d0, d1, . . . , dn are represented as different respective values (other than mere 1-bit Boolean values) in a range of possible values—e.g., where such values are percentages, fractional amounts, or the like. Such values may be unitless, although some embodiments are not limited in this regard. For example, levels d0, d1, . . . , dn may each be an integer value in a range (e.g., 0 to 10) of three or more possible integer values, for example. Alternatively, some or all of d0, d1, . . . , dn may each include a respective fractional (e.g., decimal) component.

The reference information accessed by evaluation circuit 150 may indicate various levels of degradation from a baseline state of circuitry 120—e.g., where the baseline state corresponds to a condition of device 100 at some previous stage of manufacture, sale, calibration or the like. For example, such reference information may be predefined by a manufacturer, retailer or other such external agent. In one illustrative embodiment, repository 160 is preconfigured with the reference information which may be subsequently updated one or more times by an external agent. The reference information may be based, for example, on laboratory testing, factory sampling, computer modeling and/or the like. However, some embodiments are not limited with respect to a particular means by which such reference information is determined and/or provided to device 100.

Based on the determined amount of a physical property of circuitry 130 (the amount indicated by sensor 140), and further based on reference information at repository 160, evaluation circuit 150 may select, calculate or otherwise determine a corresponding value representing an amount of degradation of circuitry 120. For example, evaluation circuit 150 may access repository 160 to perform a lookup of table 162 based on the detected signal response by circuitry 130.

In response to such determining, evaluation circuit 150 may output to another resource of device 100 (or one coupled to device 100) a signal 155 indicating the determined amount of circuit degradation. By way of illustration and not a limitation, signal 155 may result in an input/output (I/O) component of device 100—e.g., a speaker, display, haptic feedback mechanism or the like—indicating the amount of degradation to a user of device 100. Alternatively or in addition, signal 155 may result in a log, buffer, memory or other such resource of device 100 storing an indication of the determined amount of degradation. In some embodiments, signal 155 results in a wireless communication of degradation information from device 100 to an auxiliary device (e.g., a remote handheld device, a laptop or the like), to a cloud network and/or to any of a variety of other external resources. Some or all such operations may result from signal 155 being sent to circuitry 120, or another circuitry of device 100.

One or more physical properties of circuitry 130 may change over time as a result of stress induced by flexing of device 100. Accordingly, sensor 140 and evaluation circuit 130 may monitor such one or more physical properties over time—e.g., where a circuit's resistance is evaluated at a first time and subsequently evaluated at a second time after some intervening stress is imposed on circuitry 130. Based on such successive monitoring, evaluation circuit 150 may maintain a log (not shown) representing a history of circuit degradation over time. Alternatively or in addition, evaluation circuit 150 may generate an estimate of a time of failure for circuitry 120—e.g., where such an estimate is based on prediction model information (not shown) that is included, for example, in the reference information at repository 160.

Circuitry disposed in substrate 110 may be formed by lamination, photolithography and/or other techniques adapted, for example, from conventional flexible circuit techniques. In various embodiments, some or all of circuitry 120, 130 is disposed in an elastomeric matrix (not shown) that is formed in a dielectric material of flexible substrate 110. Some or all of circuitry 130 may be dedicated to communicating only signals used for detecting circuit degradation. Alternatively, at least some of circuitry 130 may be used, in one mode of device 100, to communicate a signal used for detecting circuit degradation. In such an embodiment, another mode of device 100 may couple some or all of circuitry 130—e.g., with one or more switches and/or other such circuit structures—to instead provide a supply voltage and/or one or more signals other than any used to detect circuit degradation.

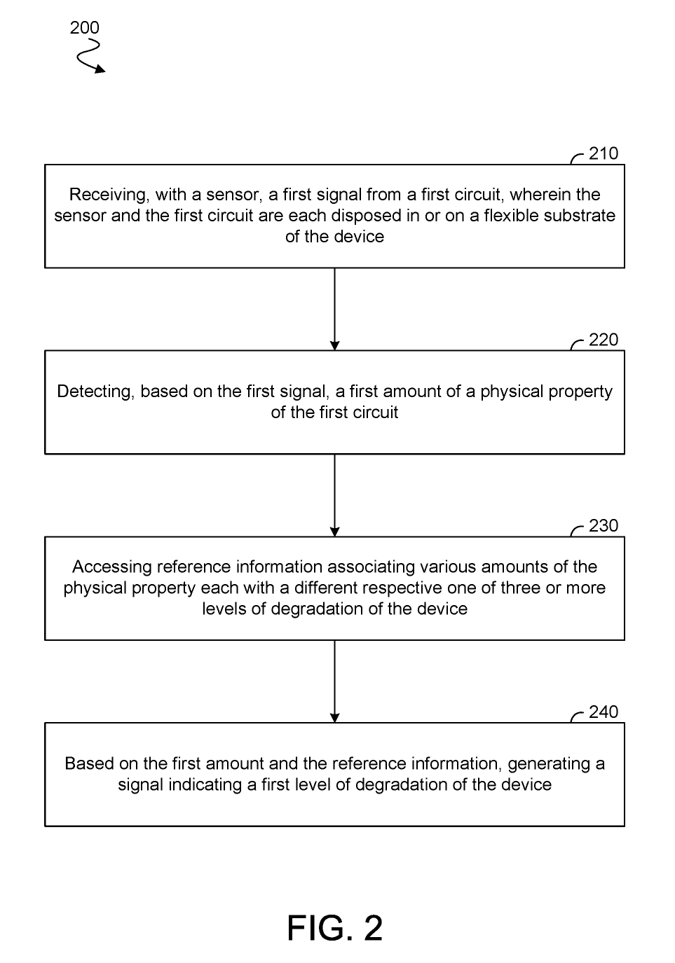

FIG. 2 illustrates elements of a method 200 to determine circuit degradation according to an embodiment. Method 200 may be performed with flexible circuitry such as that of device 100, for example. In an embodiment, method 200 includes, at 210, receiving, with a sensor, a first signal from a first circuit, wherein the sensor and the first circuit are each disposed in or on a flexible substrate of the device. The receiving at 210 may include, for example, sensor 140 receiving an output from at least a portion of circuitry 130. In one illustrative embodiment, the first circuit includes a conductive trace which extends from the sensor, along a portion of the flexible substrate, and back to the sensor to form a loop. The sensor may monitor multiple such loops—e.g., to detect respective resistances (and/or other physical properties) of each of the multiple loops.

A flexible circuit device performing method 200 may comprise other circuitry in addition to the first circuit, wherein degradation of the other circuitry is to be estimated or otherwise determined (and/or in some embodiments, predicted) by method 200. As compared to the first circuit, such other circuitry may be relatively more tolerant of stresses due to flexing of the device. For example, the other circuitry—e.g., including circuitry 120—may comprise a second circuit which is used during general purpose operation of the device (where such general purpose operation is distinguished from some or all processes to detect degradation). In such an embodiment, the second circuit may have one or more physical dimensions which are each smaller than a corresponding physical dimension of the first circuit. Alternatively or in addition, the second circuit may have a different material composition than that of the first circuit. As a result of such smaller dimension(s) and/or material composition, the second circuit may be more flexible, as compared to the first circuit. As a result, the first circuit may serve as an early warning reference structure for use in evaluating (and in some embodiment, predicting) degradation of the second circuit.

Based on the first signal received at 210, method 200 may detect, at 220, a first amount of a physical property of the first circuit. The physical property may be prone to change due to stresses imposed by flexing, over time, of the device which performs method 200. In an embodiment, the detecting at 220 includes measuring a level and/or a frequency of an output voltage or current. Such measuring may directly or indirectly indicate a resistance of the first circuit—e.g., to detect whether a break has formed in a signal path (e.g., a trace loop) of the first circuit. Alternatively or in addition, such measuring may detect an increased resistance other than that which might be attributable to any such circuit break. For example, the sensor may include amplifier circuitry to facilitate precise detection of a circuit impedance (e.g., including resistance) increases which are due to deformation and/or other stressing of a trace portion in the first circuit. In some embodiments, the detecting at 220 includes performing one or more calculations based on respective physical properties of multiple circuits including the first circuit—e.g., wherein the detecting includes calculating an overall impedance of the multiple circuits.

Method 200 may further comprise, at 230, accessing reference information associating various amounts of the physical property each with a different respective one of three or more levels of degradation of the device. The accessing at 230 may be performed by circuitry (e.g., evaluation circuit 150) that is disposed in or on a flexible substrate of the flexible circuit. Alternatively or in addition, the reference information may be stored in a memory resource (e.g., of repository 160) that is disposed in or on the flexible substrate. The reference information may include, for each of a plurality of levels of degradation, data directly or indirectly corresponding the level of degradation to a respective amount of a physical property of a trace and/or one or more other circuit structures. The plurality of levels may include one or more levels—e.g., two or more—which are between some baseline level of degradation (no degradation, for example) and some threshold level of degradation. Such a threshold level of degradation may be based on a predefined point at which circuity (e.g., some or all of circuitry 120) is expected to fail. In some embodiments, the threshold level of degradation is further based on a marginal safety factor so that excessive degradation may be indicated prior to an actual failure of the circuit performance.

The accessing at 230 may be based on only a single measurement—or alternatively, multiple measurements taken over a period of time—of the physical property (or a signal characteristic based on the physical property). By way of illustration and not limitation and not limitation, the detecting at 220 may include determining—for a given period of time—an average (e.g., a moving average), a minimum and/or a maximum of the measured value. The determined value may be used at 230 to access the reference information to determine a corresponding degradation level.

Based on the detected first amount and the reference information, method 200 may, at 240, generate a signal indicating a first level of degradation of the device. For example, method 200 may include performing a lookup of a table, linked list or other such data structure, where the lookup is based on detection of the first amount. Alternatively or in addition, method 200 may perform one or more calculations to evaluate a degradation value based on another one or more values which are retrieved from the reference information at 230. In some embodiments, method 200 determines the first level based on respective physical properties of a plurality of distinct circuit structures including the first circuit. Such circuit strictures may include, for example, different conductive loops which variously extend each across a respective region of the flexible substrate.

Although some embodiments are not limited in this regard, method 200 may include one or more additional operations (not shown) to further determine and/or communicate information describing degradation of flexible circuitry. For example, method 200 may subsequently repeat a performance of operations 210, 220, 230, 240 to determine, at a later time, a different level of circuit degradation. Alternatively or in addition, method 200 may perform additional operations based on the signal generated at 240. By way of illustration and not limitation, an I/O component may be activated to provide a video, audio and/or other indication of the first level of degradation. The generating at 240 may result in degradation information being written to a log or other memory resource which is included in, or coupled to, the flexible circuit device. In some embodiments, the signal generated at 240 results in wired or wireless communication from the flexible circuit device to another device.

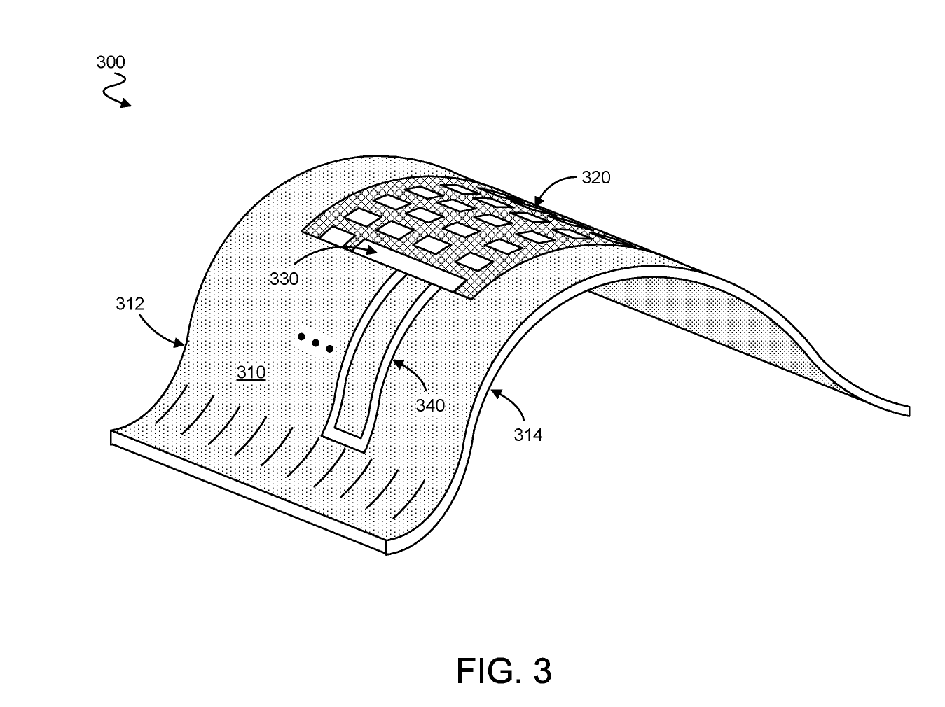

FIG. 3 illustrates elements a device 300 to detect circuit degradation according to an embodiment. Device 300 may have some or all of the features of device 100, for example. In one embodiment, method 200 is performed with circuitry of device 300. As illustrated by the flexed state of device 300 in FIG. 3, device 300 may include a flexible substrate 310 having disposed therein or thereon circuits, such as the illustrative flexible circuitry 320, which are susceptible to being variously bent, stretched, twisted or otherwise flexed along with flexible substrate 310. Over time, stress resulting from such flexing may degrade the structural integrity of at least some of flexible circuitry 320.

To detect such degradation, device 300 further comprises a circuit 340 and monitor logic 330 coupled thereto—e.g., wherein circuitry of monitor logic 330 (e.g., including some or all of sensor 140, evaluation logic 150 and repository 160) is to detect one or more physical properties of circuit 340. In the illustrative embodiment shown, circuit 340 includes one or more trace portions that each form a respective conductive loop or other signal path. Each such signal path may extend in or on flexible substrate 310—e.g., in a region between opposing sides 312, 314 thereof—to serve as a reference structure for use in estimating or otherwise determining a corresponding level degradation of some or all of circuitry 320.

By way of illustration and not limitation, monitor logic 330 may include or couple to a repository including predefined reference information which, directly or indirectly, corresponds various levels of degradation of circuitry 320 each with a respective amount of a physical property of circuitry which includes circuit 340. One or more resistometers and/or other sensors of monitor logic 330 may monitor circuit responses by circuit 340 (and/or other such circuit structures) to detect one or more physical properties thereof. Based on the detected one or more physical properties, and further based on the reference information, monitor logic 330 may determine a corresponding level of degradation of circuit 320. In one embodiment, a trace portion of circuit 340 (and/or other such reference circuit structure) is relatively more susceptible to stress, as compared to some or all conductive traces of circuitry 320.

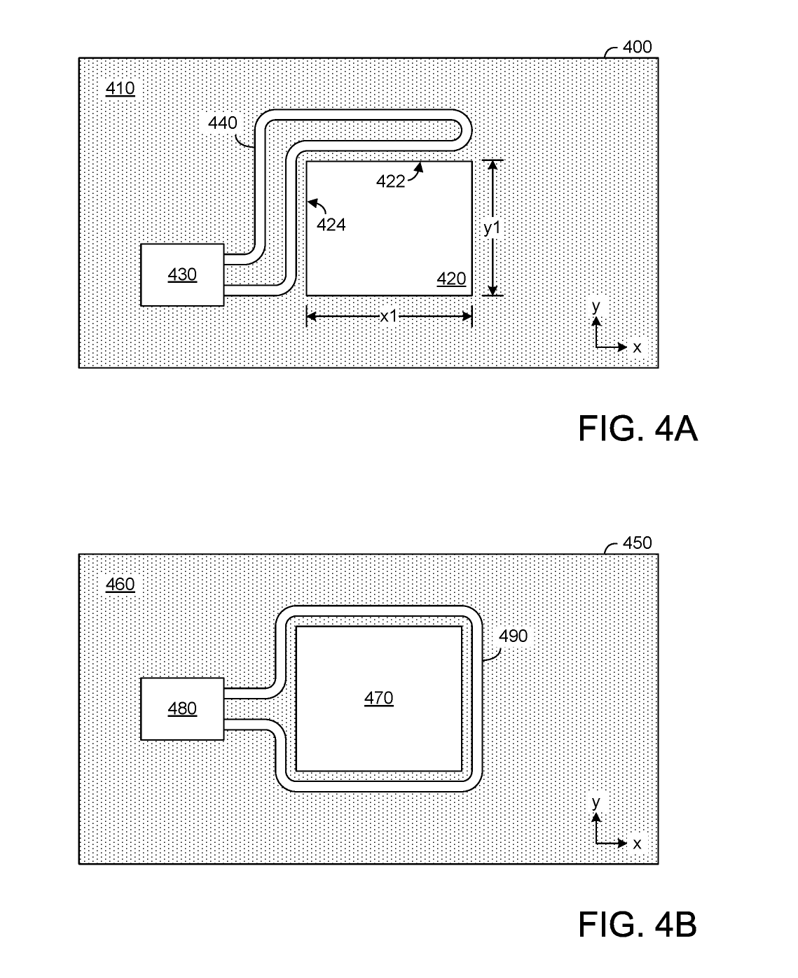

FIGS. 4A, 4B show respective devices 400, 450 each to detect circuit degradation according to a corresponding embodiment. One of both of devices 400, 450 may have features of one of devices 100, 300, for example—e.g., wherein devices 400, 450 are variously configured to perform method 200 each according to a respective embodiment.

As illustrated by the top view shown in FIG. 4A, device 400 may include a flexible substrate 410, a region 420 of which has circuitry disposed therein or thereon. Flexing of device 400 may contribute, over time, to degradation of circuitry in region 420. To detect such degradation, device 400 may further comprise additional circuit structures (such as the illustrative trace 440 shown) and monitor logic 430 coupled thereto. The extension of trace 440 across a portion of flexible substrate 410 may result in trace 440 being susceptible to stresses which correspond to those concurrently imposed on circuitry in region 420. For example, portions of trace 440 may variously extend each in parallel with (and in some embodiments, adjacent to) a respective one of at least two sides 422, 424 of region 420. In the illustrative embodiment shown, a portion of trace 440 extends along substantially all (e.g. at least 90%) of a length xl of side 422. Alternatively or in addition, another portion of trace 440 may extend along substantially all (e.g. at least 90%) of a width yl of side 424. In such an embodiment, a stress on trace 440 may correspond to a concurrent stress in region 420—e.g., where such stress is due to bending and/or stretching of flexible substrate 410 along one of both of the x-axis and the y-axis shown.

Monitor logic 430 may be coupled to receive an output from trace 440 (and/or from any of various other such circuit structures) for use in detecting a physical property thereof—e.g., according to techniques variously described herein. Based on a detected amount of the physical property, monitor logic 430 (and/or other circuitry disposed in or on flexible substrate 410) may access reference information to identify a corresponding level of degradation of circuitry in region 420. In various embodiments, some or all of monitor circuitry 430 is disposed within region 420.

As illustrated by the top view shown in FIG. 4B, device 450 may include a flexible substrate 460, a region 470 of which has disposed therein or thereon circuitry that is susceptible to degradation over time due to flexing of device 450. To detect such degradation, device 450 may further comprise a trace 490 and monitor logic 480 which (for example) correspond functionality to trace 440 and monitor logic 430, respectively. Due to its location in flexible substrate 460, trace 490 may be susceptible to stresses which correspond to those concurrently imposed on other circuitry in region 470. In the illustrative embodiment shown, trace 490 extends around a periphery of region 470. As a result, flexing of device 450 along the x-axis and/or along the y-axis may concurrently impose corresponding amounts of stress on trace 490 and circuitry in region 470.

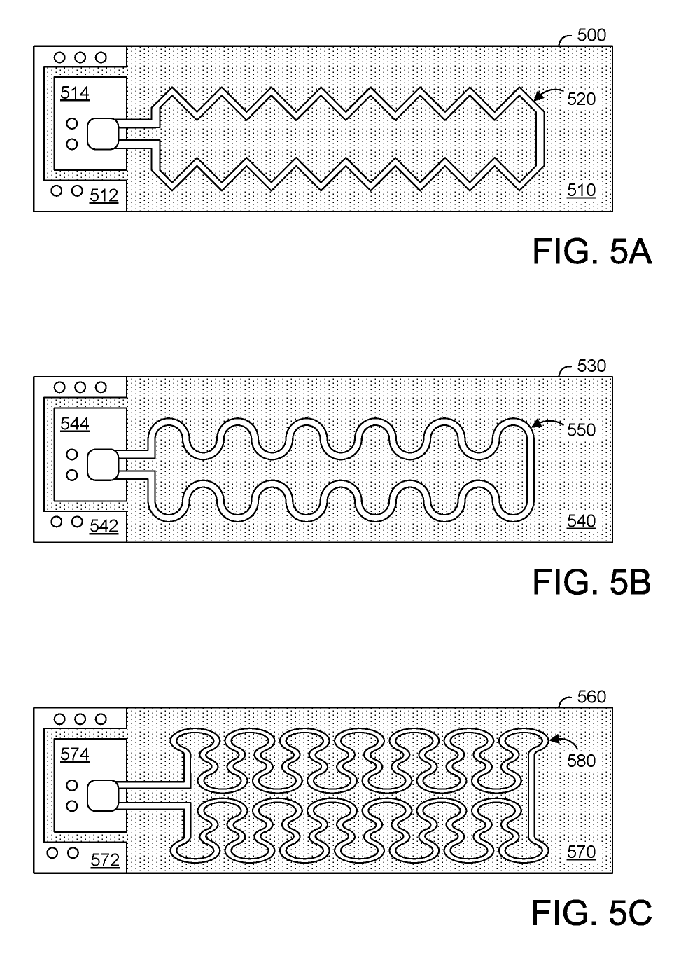

In some embodiments, circuit structures such as trace 490 or trace 440 form one or more curved and/or angled structures—referred to herein as “corrugations” (not shown)—to accommodate at least some stresses resulting from flexing. By way of illustration and not limitation, FIGS. 5A-5C show respective devices 500, 530, 560 each to detect circuit degradation according to a corresponding embodiment. Some or all of devices 500, 530, 560 may have respective features of one of devices 100, 300, 400, 450—e.g., wherein devices 500, 530, 560 are variously configured to perform method 200 each according to a respective embodiment.

As illustrated by the top view shown in FIG. 5A, device 500 may include a flexible substrate 510 having formed therein or thereon circuitry 512, monitor logic 514 and a conductive trace 520. Operation of monitor logic 514 may include detecting an amount of an impedance (or other physical property) of trace 520, where such detecting provides a basis for determining a level of degradation of circuitry 512. In the illustrative embodiment shown, trace 520 includes angled (e.g., sawtooth) corrugation structures to accommodate at least some flexing of device 500.

As shown by the top view in FIG. 5B, device 530 may include a flexible substrate 540, circuitry 542, monitor logic 544 and a conductive trace 550 which, for example, provide respective functionality corresponding to that of flexible substrate 510, circuitry 512, monitor logic 514 and conductive trace 520. In the illustrative embodiment of device 530, trace 550 includes a sine wave-shaped corrugation structure to accommodate at least some flexing of device 500. The curved corrugations of trace 550 may, for example, tolerate flexing more than the angled corrugations of trace 520.

As shown by the top view in FIG. 5C, device 560 may include a flexible substrate 570, circuitry 572, monitor logic 574 and a conductive trace 580 which, for example, provide respective functionality corresponding to that of flexible substrate 510, circuitry 512, monitor logic 514 and conductive trace 520. Trace 580 may form curved corrugation structures that, for example, are more complex than that of trace 550—e.g., where the corrugations of trace 580 tolerate flexing more than the corrugations of trace 550. The corrugation structure of traces 520, 550, 580 are merely illustrative, and traces of a flexible circuit device may have any of a variety of additional or alternative corrugation structures, in different embodiments.

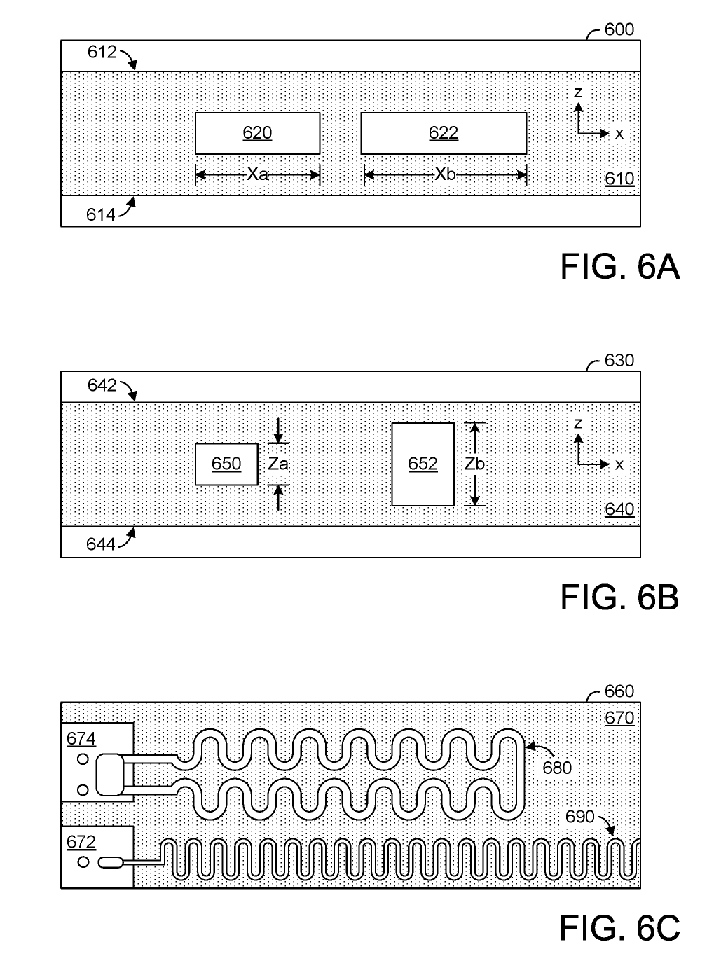

FIGS. 6A-6C show respective devices 600, 630, 660 each to detect circuit degradation according to a corresponding embodiment. Some or all of devices 600, 630, 660 may have respective features of one of devices 100, 300, 400, 450, for example—e.g., wherein devices 600, 630, 660 are variously configured to perform method 200 each according to a respective embodiment.

As illustrated by the cross-sectional side view shown in FIG. 6A, device 600 may include a flexible substrate 610 and traces 620, 622 extending, for example, between opposite sides 612, 614 of flexible substrate 610. A thickness of flexible substrate 610—as measured between sides 612, 614—may be in a range of 10 microns (μm) to 1000 μm, for example. In one embodiment, trace 622 may be coupled to monitor logic (not shown) of device 600, where a physical property of trace 622 is evaluated by such monitor logic to determine—according to techniques variously described herein—a corresponding level of degradation of circuitry including trace 620. In such an embodiment, trace 622 may be configured to serve as a reference circuit structure to provide an early indication of some future failure of trace 620. For example, an average cross-sectional length Xa (along the x-axis) of trace 620 may be less than a corresponding cross-sectional length Xb of trace 622. In one illustrative embodiment, Xa is at least ten percent (10%) smaller—e.g., at least 20% smaller—than Xb. Due at least in part to its larger width, trace 622 may be relatively stiff and less tolerant of flexing, as compared to trace 620. Accordingly, a physical property of trace 622 (where the physical property is relatively more susceptible to change due to mechanical stresses) may function as a reference for detecting, predicting or otherwise determining a corresponding state of degradation of trace 620. In an illustrative scenario according to one embodiment, one or each of Xa and Xb is in a range of 5 μm to 100 μm. However some embodiments are not limited to a particular width of circuit structures such as traces 620, 622.

As illustrated by the cross-sectional side view shown in FIG. 6B, a device 630 according to another embodiment may include a flexible substrate 640 and traces 650, 652 extending, for example, between opposite sides 642, 644 of flexible substrate 640. Trace 652 may be coupled to monitor logic (not shown) of device 630, where a physical property of trace 652 is evaluated by such monitor logic to determine a corresponding level of degradation of circuitry including trace 650. Trace 652 may serve as a reference to provide an early indication of some expected future failure of trace 650. In the illustrative embodiment shown, an average cross-sectional height Za (along the z-axis) of trace 650 may be less than a corresponding cross-sectional height Zb of trace 652. For example, Za may be at least ten percent (10%) smaller—e.g., at least 20% smaller—than Zb. Due to its relatively large height, trace 652 may be less tolerant of flexing, as compared to trace 650. In an illustrative scenario according to one embodiment, one or each of Za and Zb is in a range of 1 μm to 20 μm. However some embodiments are not limited to a particular height of circuit structures such as traces 650, 652.

As illustrated by FIGS. 6A, 6B, circuit structures may have different cross-sectional dimensions to provide different respective levels of tolerance for flexing—e.g., where one such circuit structure is to be monitored as a reference for determining degradation of another such circuit structure. Such various levels of tolerance may additionally or alternatively by provided by circuit structures forming different respective corrugations. By way of illustration and not limitation, a trace of circuitry 130 may have a relatively less flexible corrugation pattern (such as that of trace portion 520), wherein one or more traces of circuitry 120 instead forms another corrugation pattern (such as that of trace 550 or trace 580) which is more tolerant of bending and/or other flexing.

In some embodiments, such circuit structures have different respective levels of flexibility due to a combination of different dimensions and different corrugation characteristics. For example, as shown by FIG. 6C, device 660 may include a flexible substrate 670, circuitry 672, monitor logic 674 and a conductive trace 680 which, for example, provide respective functionality corresponding to that of flexible substrate 510, circuitry 512, monitor logic 514 and conductive trace 520.

Circuitry 672 may include or couple to another trace 690 that is coupled to communicate one or more signals, voltages and/or the like with other circuitry (not shown) of device 600 across a portion of flexible substrate 670. Monitor logic 674 may monitor a physical property of trace 680 to determine a level of degradation of trace 690 and/or circuitry 672. In the illustrative embodiment of device 660, trace 680 includes corrugation structures to accommodate at least some flexing of device 660. However, as compared to trace 690 (and/or circuitry 672), trace 680 may be relatively less tolerant of such flexing. For example, an average cross-sectional width of trace 680 may be greater than a corresponding average cross-sectional width of trace 690. Alternatively or in addition, individual corrugations of trace 690 may span relatively shorter distances, as compared to individual corrugations of trace 680.

Although some embodiments are not limited in this regard, circuit structures—e.g., including respective traces of circuitry 120 and circuitry 130—may have different levels of flexibility due at least in part to the respective material compositions thereof. By way of illustration and not limitation, circuitry 120, 130 may each include a respective one or more of copper (Cu), zinc (Zn), iron (Fe), nickel (Ni) and/or other metals used in conventional circuit traces. In such an embodiment, a first fraction of a metal in one or more traces of circuitry 130 may be different than a second mass fraction of the same metal in one or more traces in circuitry 120—e.g., by at least 5% (and, in some embodiments, by at least 10%) of the second mass fraction. The difference in such material compositions may contribute to such one or more traces in circuitry 130 being less flexible, as compared to the one or more traces in circuitry 130.

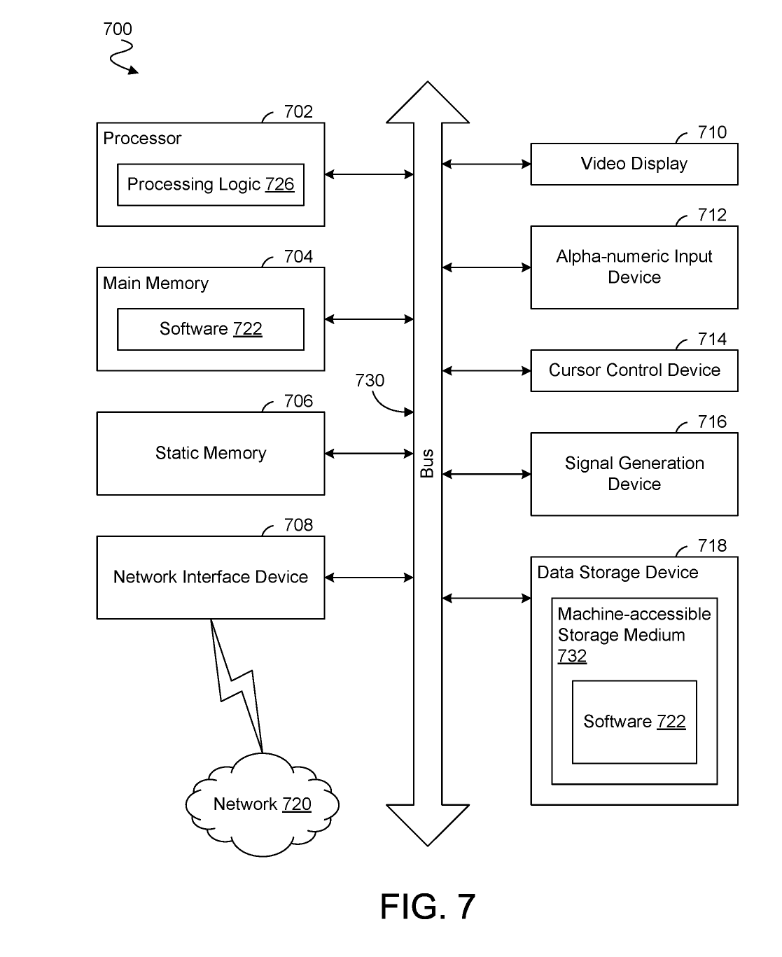

FIG. 7 illustrates a diagrammatic representation of a machine in the exemplary form of a computer system 700 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 700 includes a processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

Processor 702 represents one or more general-purpose processing devices such as a microprocessor, central processing unit, or the like. More particularly, the processor 702 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 702 may also be one or more special-purpose processing devices such as an application specific integrated circuit (ASIC), a field programmable gate array (FPGA), a digital signal processor (DSP), network processor, or the like. Processor 702 is configured to execute the processing logic 726 for performing the operations described herein.

The computer system 700 may further include a network interface device 708. The computer system 700 also may include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium (or more specifically a computer-readable storage medium) 732 on which is stored one or more sets of instructions (e.g., software 722) embodying any one or more of the methodologies or functions described herein. The software 722 may also reside, completely or at least partially, within the main memory 704 and/or within the processor 702 during execution thereof by the computer system 700, the main memory 704 and the processor 702 also constituting machine-readable storage media. The software 722 may further be transmitted or received over a network 720 via the network interface device 708.

While the machine-accessible storage medium 732 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any of one or more embodiments. The term “machine-readable storage medium” shall accordingly be taken to include, but not be limited to, solid-state memories, and optical and magnetic media.

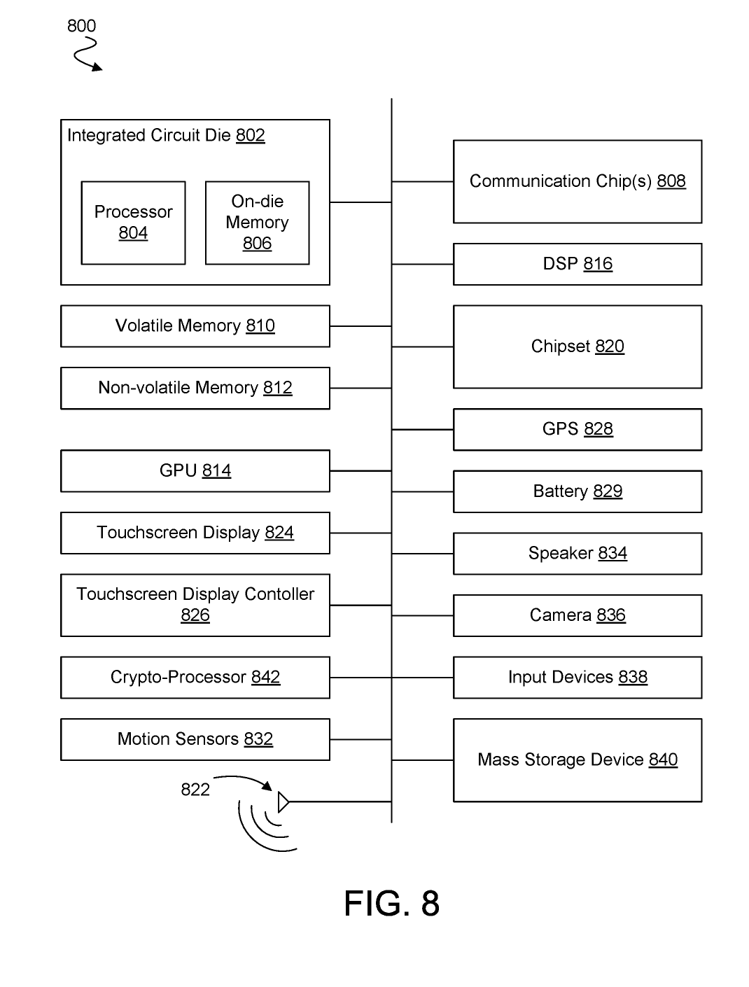

FIG. 8 illustrates a computing device 800 in accordance with one embodiment. The computing device 800 may include a number of components. In one embodiment, these components are attached to one or more motherboards. In an alternate embodiment, these components are fabricated onto a single system-on-a-chip (SoC) die rather than a motherboard. The components in the computing device 800 include, but are not limited to, an integrated circuit die 802 and at least one communication chip 808. In some implementations the communication chip 808 is fabricated as part of the integrated circuit die 802. The integrated circuit die 802 may include a CPU 804 as well as on-die memory 806, often used as cache memory, that can be provided by technologies such as embedded DRAM (eDRAM) or spin-transfer torque memory (STTM or STTM-RAM).

Computing device 800 may include other components that may or may not be physically and electrically coupled to the motherboard or fabricated within an SoC die. These other components include, but are not limited to, volatile memory 810 (e.g., DRAM), non-volatile memory 812 (e.g., ROM or flash memory), a graphics processing unit 814 (GPU), a digital signal processor 816, a crypto processor 842 (a specialized processor that executes cryptographic algorithms within hardware), a chipset 820, an antenna 822, a display or a touchscreen display 824, a touchscreen controller 826, a battery 829 or other power source, a power amplifier (not shown), a global positioning system (GPS) device 828, a compass 830, a motion coprocessor or sensors 832 (that may include an accelerometer, a gyroscope, and a compass), a speaker 834, a camera 836, user input devices 838 (such as a keyboard, mouse, stylus, and touchpad), and a mass storage device 840 (such as hard disk drive, compact disk (CD), digital versatile disk (DVD), and so forth).

The communications chip 808 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 808 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 808. For instance, a first communication chip 808 may be dedicated to shorter range wireless communications such as Wi-Fi and Bluetooth and a second communication chip 808 may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory. In various embodiments, the computing device 800 may be a laptop computer, a netbook computer, a notebook computer, an ultrabook computer, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 800 may be any other electronic device that processes data.

In one implementation, a device comprises a flexible substrate, first circuitry and second circuitry, a sensor coupled to receive a first signal from the first circuitry, and an evaluation circuit coupled to the sensor, the evaluation circuit configured to detect, based on the first signal, a first amount of a physical property of the first circuitry. The device further comprises a repository to store reference information which associates various amounts of the physical property each with a different respective one of three or more levels of degradation of the second circuitry, wherein the evaluation circuit further to access the reference information and, based on the first amount and the reference information, to generate a signal which indicates a first level of degradation of the second circuitry, and wherein the first circuitry, the second circuitry, the sensor, the evaluation circuit and the repository are each disposed in or on the flexible substrate.

In one embodiment, the physical property includes a resistance. In another embodiment, the evaluation circuit to detect the first amount includes the evaluation circuit to calculate an average of multiple values each based on the physical property. In another embodiment, the evaluation circuit to detect the first amount includes the evaluation circuit to identify a value as a minimum of multiple values each based on the physical property. In another embodiment, the second circuitry is disposed in a region of the flexible substrate, wherein the first circuitry includes a first trace portion which extends along a first side of the region and a second trace portion which extends along a second side of the region. In another embodiment, the first circuitry includes a trace which extends around a periphery of the region. In another embodiment, the first circuitry includes a first trace portion and the second circuitry includes a second trace portion, wherein a first mass fraction of a metal in the first trace portion differs from a second mass fraction of the metal in the second trace portion by at least 5% of the second mass fraction. In another embodiment, the first circuitry includes a first trace portion and the second circuitry includes a second trace portion, wherein an average of a cross-sectional dimension of the second trace portion is at least 10% smaller than an average of a corresponding cross-sectional dimension of the first trace portion.

In another implementation, a method at a flexible circuit device comprises receiving, with a sensor, a first signal from a first circuit, wherein the sensor and the first circuit are each disposed in or on a flexible substrate of the flexible circuit device, detecting, based on the first signal, a first amount of a physical property of the first circuit, accessing reference information associating various amounts of the physical property each with a different respective one of three or more levels of degradation of the device, and based on the first amount and the reference information, generating a signal indicating a first level of degradation of the device.

In one embodiment, wherein the physical property includes a resistance. In another embodiment, detecting the first amount includes calculating an average of multiple values each based on the physical property. In another embodiment, detecting the first amount includes identifying a value as a minimum of multiple values each based on the physical property. In another embodiment, the signal represents a level of degradation of a second circuit disposed in a region of the flexible substrate, wherein the first circuit includes a first trace portion which extends along a first side of the region and a second trace portion which extends along a second side of the region. In another embodiment, the first circuit includes a trace which extends around a periphery of the region. In another embodiment, the first circuit includes a first trace portion, wherein the signal represents a level of degradation of a second circuit comprising a second trace portion. In another embodiment, a first mass fraction of a metal in the first trace portion differs from a second mass fraction of the metal in the second trace portion by at least 5% of the second mass fraction. In another embodiment, an average of a cross-sectional dimension of the second trace portion is at least 10% smaller than an average of a corresponding cross-sectional dimension of the first trace portion.

In another implementation, a system comprises a flexible circuit device including a flexible substrate, first circuitry and second circuitry, a sensor coupled to receive a first signal from the first circuitry, and an evaluation circuit coupled to the sensor, the evaluation circuit configured to detect, based on the first signal, a first amount of a physical property of the first circuitry. The flexible circuit device further comprises a repository to store reference information which associates various amounts of the physical property each with a different respective one of three or more levels of degradation of the second circuitry, wherein the evaluation circuit further to access the reference information and, based on the first amount and the reference information, to generate a signal which indicates a first level of degradation of the second circuitry, and wherein the first circuitry, the second circuitry, the sensor, the evaluation circuit and the repository are each disposed in or on the flexible substrate. The system further comprises a display device coupled to the flexible circuit device, the display device to display an image based on signals exchanged with the second circuitry.

In one embodiment, the physical property includes a resistance. In another embodiment, the evaluation circuit to detect the first amount includes the evaluation circuit to calculate an average of multiple values each based on the physical property. In another embodiment, the evaluation circuit to detect the first amount includes the evaluation circuit to identify a value as a minimum of multiple values each based on the physical property. In another embodiment, the second circuitry is disposed in a region of the flexible substrate, wherein the first circuitry includes a first trace portion which extends along a first side of the region and a second trace portion which extends along a second side of the region. In another embodiment, the first circuitry includes a trace which extends around a periphery of the region. In another embodiment, the first circuitry includes a first trace portion and the second circuitry includes a second trace portion, wherein a first mass fraction of a metal in the first trace portion differs from a second mass fraction of the metal in the second trace portion by at least 5% of the second mass fraction. In another embodiment, the first circuitry includes a first trace portion and the second circuitry includes a second trace portion, wherein an average of a cross-sectional dimension of the second trace portion is at least 10% smaller than an average of a corresponding cross-sectional dimension of the first trace portion.

Techniques and architectures for evaluating degradation of flexible circuitry are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

1. A device comprising:
a flexible substrate;
first circuitry and second circuitry;
a sensor coupled to receive a first signal from the first circuitry, wherein the first signal is indicative of stress imposed on the first circuitry or second circuitry by flexing the first circuitry or second circuitry;
an evaluation circuit coupled to the sensor, the evaluation circuit configured to detect, based on the first signal, a first amount of a physical property of the first circuitry; and
a repository to store reference information which associates various amounts of the physical property each with a different respective one of three or more levels of degradation of the second circuitry;
wherein the evaluation circuit further to access the reference information and, based on the first amount and the reference information, to generate a signal which indicates a first level of degradation of the second circuitry; and
wherein the first circuitry, the second circuitry, the sensor, the evaluation circuit and the repository are each disposed in or on the flexible substrate.

2. The device of claim 1, wherein the physical property includes a resistance.

3. The device of claim 1, wherein the evaluation circuit to detect the first amount includes the evaluation circuit to calculate an average of multiple values each based on the physical property.

4. The device of claim 1, wherein the evaluation circuit to detect the first amount includes the evaluation circuit to identify a value as a minimum of multiple values each based on the physical property.

5. The device of claim 1, wherein the second circuitry is disposed in a region of the flexible substrate, wherein the first circuitry includes a first trace portion which extends along a first side of the region and a second trace portion which extends along a second side of the region.

6. The device of claim 5, wherein the first circuitry includes a trace which extends around a periphery of the region.

7. The device of claim 1, wherein the first circuitry includes a first trace portion and the second circuitry comprising a second trace portion, wherein a first mass fraction of a metal in the first trace portion differs from a second mass fraction of the metal in the second trace portion by at least 5% of the second mass fraction.

8. The device of claim 1, wherein the first circuitry includes a first trace portion and the second circuitry comprising a second trace portion, wherein an average of a cross-sectional dimension of the second trace portion is at least 10% smaller than an average of a corresponding cross-sectional dimension of the first trace portion.

9. A method at a flexible circuit device, the method comprising:
receiving, with a sensor, a first signal from a first circuit, wherein the sensor and the first circuit are each disposed in or on a flexible substrate of the flexible circuit device, wherein the first signal is indicative of stress imposed on the first circuit by flexing the first circuit;
detecting, based on the first signal, a first amount of a physical property of the first circuit;
accessing reference information associating various amounts of the physical property each with a different respective one of three or more levels of degradation of the device; and
based on the first amount and the reference information, generating a signal indicating a first level of degradation of the device.

10. The method of claim 9, wherein the physical property includes a resistance.

11. The method of claim 9, wherein detecting the first amount includes calculating an average of multiple values each based on the physical property.

12. The method of claim 9, wherein detecting the first amount includes identifying a value as a minimum of multiple values each based on the physical property.

13. The method of claim 9, wherein the signal represents a level of degradation of a second circuit disposed in a region of the flexible substrate, wherein the first circuit includes a first trace portion which extends along a first side of the region and a second trace portion which extends along a second side of the region.

14. The method of claim 13, wherein the first circuit includes a trace which extends around a periphery of the region.

15. The method of claim 9, wherein the first circuit includes a first trace portion, wherein the signal represents a level of degradation of a second circuit comprising a second trace portion.

16. The method of claim 15, wherein a first mass fraction of a metal in the first trace portion differs from a second mass fraction of the metal in the second trace portion by at least 5% of the second mass fraction.

17. The method of claim 15, wherein an average of a cross-sectional dimension of the second trace portion is at least 10% smaller than an average of a corresponding cross-sectional dimension of the first trace portion.

18. A system comprising:
a flexible circuit device including:
a flexible substrate;
first circuitry and second circuitry;
a sensor coupled to receive a first signal from the first circuitry, wherein the first signal is indicative of stress imposed on the first circuitry or second circuitry by flexing the first circuitry or second circuitry;
an evaluation circuit coupled to the sensor, the evaluation circuit configured to detect, based on the first signal, a first amount of a physical property of the first circuitry; and
a repository to store reference information which associates various amounts of the physical property each with a different respective one of three or more levels of degradation of the second circuitry;
wherein the evaluation circuit further to access the reference information and, based on the first amount and the reference information, to generate a signal which indicates a first level of degradation of the second circuitry; and
wherein the first circuitry, the second circuitry, the sensor, the evaluation circuit and the repository are each disposed in or on the flexible substrate; and
a display device coupled to the flexible circuit device, the display device to display an image based on signals exchanged with the second circuitry.

19. The system of claim 18, wherein the physical property includes a resistance.

20. The system of claim 18, wherein the evaluation circuit to detect the first amount includes the evaluation circuit to calculate an average of multiple values each based on the physical property.

21. The system of claim 18, wherein the evaluation circuit to detect the first amount includes the evaluation circuit to identify a value as a minimum of multiple values each based on the physical property.

22. The system of claim 18, wherein the second circuitry is disposed in a region of the flexible substrate, wherein the first circuitry includes a first trace portion which extends along a first side of the region and a second trace portion which extends along a second side of the region.
